(19) United States
(12) Patent Application Publication
(10) Pub. No.: US 2024/0385395 A1
(43) Pub. Date: Nov. 21, 2024

(54) OPTICAL DEVICE AND METHOD OF MANUFACTURE

(71) Applicant: Taiwan Semiconductor Manufacturing Co, Ltd., Hsinchu (TW)

(72) Inventors: Ming-Fa Chen, Taichung City (TW); Shang-Yun Hou, Jubei City (TW)

(21) Appl. No.: 18/467,020

(22) Filed: Sep. 14, 2023

Related U.S. Application Data
(60) Provisional application No. 63/502,686, filed on May 17, 2023.

(51) Int. Cl. G02B 6/42

(52) U.S. Cl. CPC G02B 6/4214; G02B 6/4245

(57) ABSTRACT

In an embodiment, a method includes: forming an optical package, forming the optical package comprising: forming optical devices over a substrate; forming a first interconnect structure over the optical devices; and attaching a first semiconductor device to the optical devices; attaching a second semiconductor device to an interposer substrate; attaching the optical package to the interposer substrate; and attaching an optical port adjacent to the optical package, the optical port comprising: an optical fiber; and an optical redirection structure configured to redirect an optical signal between a first pathway and a second pathway, the first pathway being parallel with a major surface of the interposer substrate, the second pathway being non-parallel with the major surface of the interposer substrate.

### PRIORITY CLAIM AND CROSS-REFERENCE

This application claims the benefit of U.S. Provisional Application No. 63/502,686, filed on May 17, 2023, which application is hereby incorporated herein by reference.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 illustrate formation of an optical interposer, in accordance with some embodiments.

FIGS. 6-8 illustrate formation of optical package including an optical interposer, in accordance with some embodiments.

FIGS. 9-12E illustrate inclusion of an optical package into semiconductor packages, in accordance with some embodiments.

FIGS. 13-15 illustrate inclusion of an optical package into a semiconductor package, in accordance with some embodiments.

FIGS. 16-17 illustrate inclusion of an optical package into a semiconductor package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments provided herein are discussed with respect to forming a photonic integrated circuit (PIC) device (e.g., an optical interposer) and attaching an electronic integrated circuit (EIC) device (e.g., a semiconductor device) to the PIC device to form an optical package such as a compact universal photonic engine (COUPE). For example, the PIC device may include optical devices (e.g., edge couplers) to receive or transmit optical signals. The COUPE is incorporated into a semiconductor package, and an optical port (e.g., comprising a fiber array unit) is attached to provide optical input/output to the edge couplers, which can facilitate high-bandwidth signals. The optical port further includes a component (e.g., a prism or a reflector) to redirect an optical signal between a first pathway in relation to the edge couplers and a second pathway in relation to the fiber array unit, wherein the first pathway and the second pathway may be, e.g., substantially perpendicular to one another. It should be appreciated that the embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

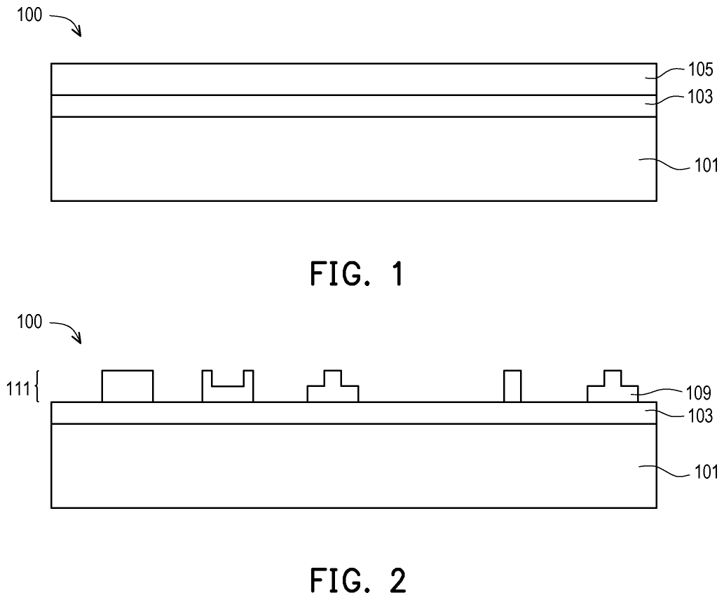

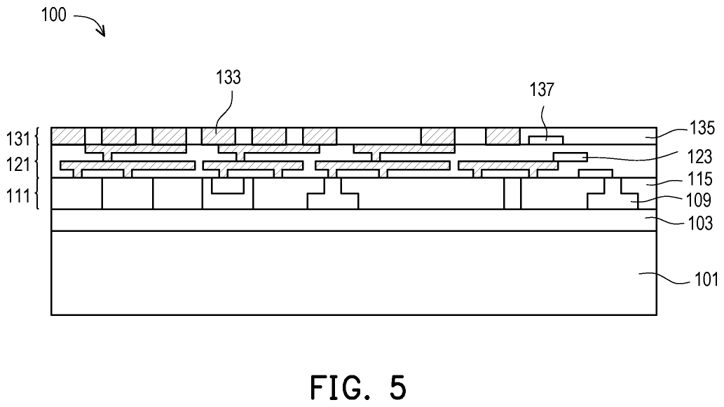

With reference now to FIG. 1, there is illustrated an initial structure of an optical interposer 100 (see FIG. 5), in accordance with some embodiments. In the particular embodiment illustrated in FIG. 1, the optical interposer 100 is a photonic integrated circuit (PIC) device and comprises at this stage a first substrate 101, a first insulator layer 103, and a layer of material 105 for a first active layer 111 of first optical components 109 (not separately illustrated in FIG. 1 but illustrated and discussed further below with respect to FIG. 2). In an embodiment, at a beginning of the manufacturing process of the optical interposer 100, the first substrate 101, the first insulator layer 103, and the layer of material 105 for the first active layer 111 of first optical components 109 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 111 and can additionally, in some embodiments, serve as a portion of cladding material that surrounds the subsequently manufactured first optical components 109 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 111 is initially (prior to patterning) a conformal layer of material that will be used to begin manufacturing the first active layer 111 of the first optical components 109. In an embodiment the material 105 for the first active layer 111 may be a translucent material that can be used as a core material for the desired first optical components 109, such as a semiconductor material such as silicon, germanium, silicon germanium, combinations of these, or the like, while in other embodiments the material 105 for the first active layer 111 may be a dielectric material such as silicon nitride or the like, although in other embodiments the material 105 for the first active layer 111 may be III-V materials, lithium niobate materials, or polymers. In embodiments in which the material 105 of the first active layer 111 is deposited, the material 105 for the first active layer 111 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 111 may initially be part of the first substrate 101 prior to the implantation process to form the first insulation layer 103. However, any suitable materials and methods of manufacture may be utilized to form the material 105 of the first active layer 111.

FIG. 2 illustrates that, once the material 105 for the first active layer 111 is ready, the first optical components 109 for the first active layer 111 are manufactured using the material 105 for the first active layer 111. In embodiments the first optical components 109 of the first active layer 111 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 109 may be used.

In accordance with various embodiments, the optical components 109 include edge couplers 109E, which are configured to receive optical signals into the optical interposer 100 and/or transmit optical signals from the optical interposer 100. The edge couplers 109E may be able to facilitate a higher bandwidth of optical signals as compared to analogous components such as grating couplers. The edge couplers 109E transmit/receive in a lateral (e.g., horizontal) direction in relation to the optical interposer 100. As such, embodiments of a semiconductor package discussed in greater detail below are intended to facilitate horizontal pathways of the optical signal.

To begin forming the first active layer 111 of first optical components 109 from the initial material, the material 105 for the first active layer 111 may be patterned into the desired shapes for the first active layer 111 of first optical components 109. In an embodiment the material 105 for the first active layer 111 may be patterned using, e.g., one or more photolithographic masking and etching processes. However, any suitable method of patterning the material 105 for the first active layer 111 may be utilized. For some of the first optical components 109, such as waveguides or edge couplers, the patterning process may be all or at least most of the manufacturing that is used to form these first optical components 109.

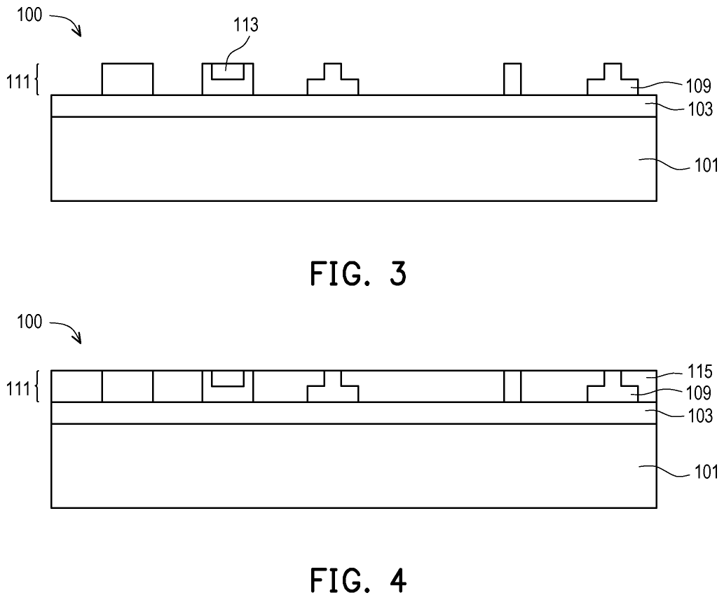

FIG. 3 illustrates that, for those components that utilize further manufacturing processes, such as Mach-Zehnder silicon-photonic switches that utilize resistive heating elements, additional processing may be performed either before or after the patterning of the material for the first active layer 111. For example, implantation processes, additional deposition and patterning processes for different materials (e.g., resistive heating elements, III-V materials for converters), combinations of all of these processes, or the like, can be utilized to help further the manufacturing of the various desired first optical components 109. In a particular embodiment, and as specifically illustrated in FIG. 3, in some embodiments an epitaxial deposition of a semiconductor material 113 such as germanium (used, e.g., for electricity/optics signal modulation and transversion) may be performed on a patterned portion of the material 105 of the first active layer 111. In such an embodiment the semiconductor material 113 may be epitaxially grown in order to help manufacture, e.g., a photodiode for an optical-to-electrical converter. All such manufacturing processes and all suitable first optical components 109 may be manufactured, and all such combinations are fully intended to be included within the scope of the embodiments.

FIG. 4 illustrates that, once the individual first optical components 109 of the first active layer 111 have been formed, a second insulating layer 115 may be deposited to cover the first optical components 109 and provide additional cladding material. In an embodiment the second insulator layer 115 may be a dielectric layer that separates the individual components of the first active layer 111 from each other and from the overlying structures and can additionally serve as another portion of cladding material that surrounds the first optical components 109. In an embodiment the second insulator layer 115 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulating layer 115 has been deposited, the material may be planarized using, e.g., a chemical mechanical polishing process in order to either planarize a top surface of the second insulating layer 115 (in embodiments in which the second insulating layer 115 is intended to fully cover the first optical components 109) or else planarize the second insulating layer 115 with top surfaces of the first optical components 109. However, any suitable material and method of manufacture may be used.

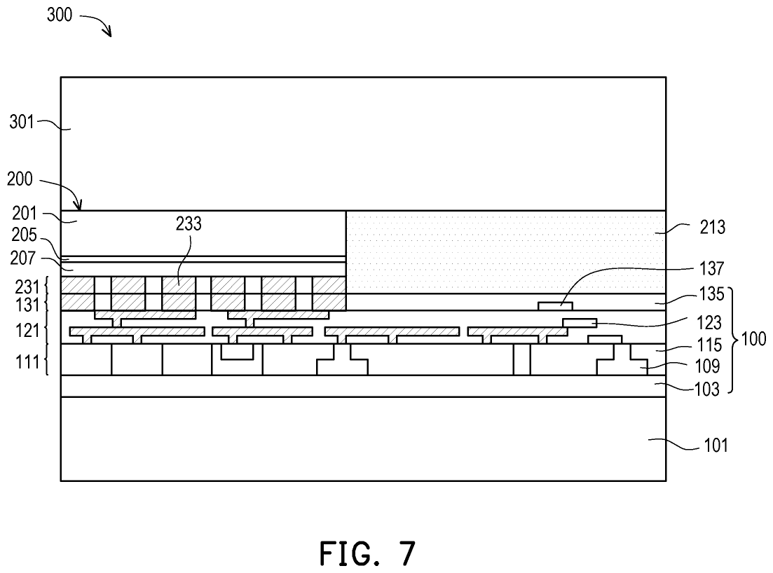

FIG. 5 illustrates that, once the first optical components 109 of the first active layer 111 have been manufactured and the second insulating layer 115 has been formed, first metallization layers 121 are formed in order to electrically connect the first active layer 111 of first optical components 109 to control circuitry, to each other, and to subsequently attached devices (not illustrated in FIG. 5 but illustrated and described further below with respect to FIG. 7). In an embodiment the first metallization layers 121 are formed of alternating layers of dielectric and conductive material and may be formed through any suitable processes (such as deposition, damascene, dual damascene, etc.). In particular embodiments there may be multiple layers of metallization used to interconnect the various first optical components 109, but the precise number of first metallization layers 121 is dependent upon the design of the optical interposer 100.

Additionally, during the manufacture of the first metallization layers 121, one or more second optical components 123 may be formed as part of the first metallization layers 121. In some embodiments the second optical components 123 of the first metallization layers 121 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 123.

In an embodiment the one or more second optical components 123 may be formed by initially depositing a material for the one or more second optical components 123. In an embodiment the material for the one or more second optical components 123 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 123 has been deposited or otherwise formed, the material may be patterned into the desired shapes for the one or more second optical components 123. In an embodiment the material of the one or more second optical components 123 may be patterned using, e.g., one or more photolithographic masking and etching processes. However, any suitable method of patterning the material for the one or more second optical components 123 may be utilized.

For some of the one or more second optical components 123, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 123. For example, implantation processes, additional deposition and patterning processes for different materials, combinations of all of these processes, or the like, and can be utilized to help further the manufacturing of the various desired one or more second optical components 123. All such manufacturing processes and all suitable one or more second optical components 123 may be manufactured, and all such combinations are fully intended to be included within the scope of the embodiments.

Once the one or more second optical components 123 of the first metallization layers 121 have been manufactured, a first bonding layer 131 is formed over the first metallization layers 121. In an embodiment, the first bonding layer 131 may be used for a dielectric-to-dielectric and metal-to-metal bond. In accordance with some embodiments, the first bonding layer 131 is formed of a first dielectric material 135 such as silicon oxide, silicon nitride, or the like. The first dielectric material 135 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 135 has been formed, first openings in the first dielectric material 135 are formed to expose conductive portions of the underlying layers in preparation to form first bond pads 133 within the first bonding layer 131. Once the first openings have been formed within the first dielectric material 135, the first openings may be filled with a seed layer and a plate metal to form the first bond pads 133 within the first dielectric material 135. The seed layer may be blanket deposited over top surfaces of the first dielectric material 135 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 135 and sidewalls of the openings and the second openings before the seed layer. The barrier layer may comprise titanium, titanium nitride, tantalum, tantalum nitride, or the like.

Following the filling of the first openings, a planarization process, such as a chemical mechanical polishing (CMP), is performed to remove excess portions of the seed layer and the plate metal, forming the first bond pads 133 within the first bonding layer 131. In some embodiments a bond pad via (not separately illustrated) may also be utilized to connect the first bond pads 133 with underlying conductive portions and, through the underlying conductive portions, connect the first bond pads 133 with the first metallization layers 121.

Additionally, the first bonding layer 131 may also include one or more third optical components 137 incorporated within the first bonding layer 131. In such an embodiment, prior to the deposition of the first dielectric material 135, the one or more third optical components 137 may be manufactured using similar methods and similar materials as the one or more second optical components 123 (described above), such as by being waveguides and other structures formed at least in part through a deposition and patterning process. However, any suitable structures, materials and any suitable methods of manufacture may be utilized.

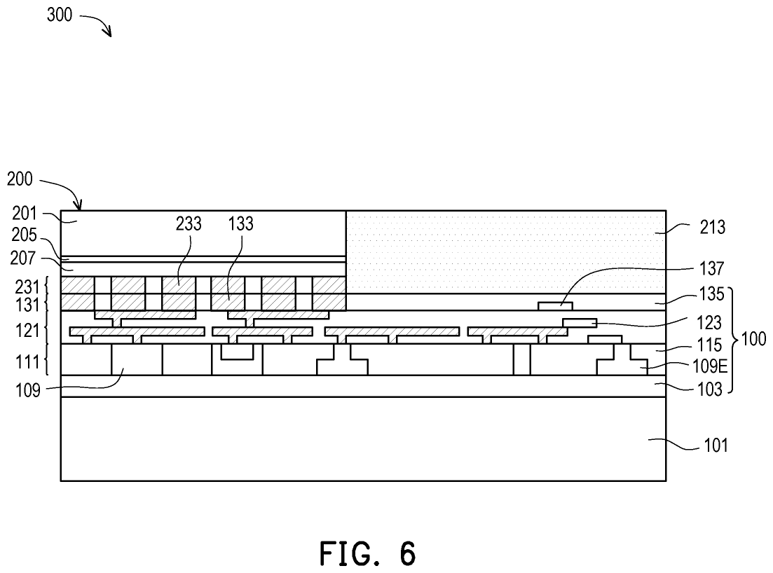

FIG. 6 illustrates a bonding of a first semiconductor device 200 to the optical interposer 100. In some embodiments, the first semiconductor device 200 is an electronic integrated circuit (EIC) device (e.g., a device without optical devices) and may have a semiconductor substrate 201, a layer of active devices 205, an overlying interconnect structure 207, a second bond layer 231, and associated third bond pads 233. In an embodiment, the semiconductor substrate 201 may be similar to the first substrate 101 (e.g., a semiconductor material such as silicon or silicon germanium), the active devices 205 may be transistors, capacitors, resistors, and the like formed over the semiconductor substrate 201, the interconnect structure 207 may be similar to the first metallization layers 121 (without optical components), the second bond layer 231 may be similar to the first bond layer 131, and the third bond pads 233 may be similar to the first bond pads 133. However, any suitable devices may be utilized.

In an embodiment the first semiconductor device 200 may be configured to work with the optical interposer 100 for a desired functionality. In some embodiments the first semiconductor device 200 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

Once the first semiconductor device 200 has been prepared, the first semiconductor device 200 may be bonded to the optical interposer 100 to form an optical package 300. In an embodiment, the first semiconductor device 200 may be bonded to the optical interposer 100 using, e.g., a dielectric-to-dielectric and metal-to-metal bonding process. In such an embodiment, the first semiconductor device 200 is bonded to the first bonding layer 131 of the optical interposer 100 by bonding both the first bond pads 133 to the third bond pads 233 and by bonding the dielectrics within the first bonding layer 131 to the dielectrics within the second bond layer 231. In this embodiment, the top surfaces of the first semiconductor device 200 and the optical interposer 100 may first be activated utilizing, e.g., a dry treatment, a wet treatment, a plasma treatment, exposure to an inert gas, exposure to H₂, exposure to N₂, exposure to O₂, or combinations thereof, as examples. However, any suitable activation process may be utilized.

After the activation process, the first semiconductor device 200 and the optical interposer 100 may be cleaned using, e.g., a chemical rinse, and then the first semiconductor device 200 is aligned and placed into physical contact with the optical interposer 100. The first semiconductor device 200 and the optical interposer 100 are then subjected to thermal treatment and contact pressure to bond the first semiconductor device 200 and the optical interposer 100. For example, the first semiconductor device 200 and the optical interposer 100 may be subjected to a pressure of about 200 kPa or less, and a temperature between about 25° C. and about 250° C. to fuse the first semiconductor device 200 and the optical interposer 100. The first semiconductor device 200 and the optical interposer 100 may then be subjected to a temperature at or above the eutectic point for material of the first bond pads 133, e.g., between about 150° C. and about 650° C., to fuse the metal bond pads. In this manner, the first semiconductor device 200 and the optical interposer 100 form a bonded device (e.g., the optical package 300, which may be referred to as a COUPE device). In some embodiments, the bonded dies are subsequently baked, annealed, pressed, or otherwise treated to strengthen or finalize the bond.

Additionally, while the above description describes a dielectric-to-dielectric and metal-to-metal bonding process, this is intended to be illustrative and is not intended to be limiting. In yet other embodiments, the optical interposer 100 may be bonded to the first semiconductor device 200 by metal-to-metal bonding, or another bonding process. For example, the first semiconductor device 200 and the optical interposer 100 may be bonded by metal-to-metal bonding that is achieved by fusing conductive elements. Any suitable bonding process may be utilized, and all such methods are fully intended to be included within the scope of the embodiments.

FIG. 6 additionally illustrates that, once the first semiconductor device 200 has been bonded, a gap-fill material 213 is deposited in order to fill the spaces between adjacent ones of the first semiconductor devices 200 and provide additional support. In an embodiment, the gap-fill material 213 may be a material such as silicon oxide, silicon nitride, silicon oxynitride, combinations of these, or the like, deposited to fill and overfill the spaces between the first semiconductor devices 200. However, any suitable material and method of deposition may be utilized.

Once the gap-fill material 213 has been deposited, the gap-fill material 213 may be planarized in order to expose the first semiconductor device 200. In an embodiment the planarization process may be a chemical mechanical planarization process, a grinding process, or the like. However, any suitable planarization process may be utilized.

FIG. 7 illustrates an attachment of a support substrate 301 to the first semiconductor device 200 and the gap-fill material 213. In an embodiment, the support substrate 301 may be a support material that is transparent to the wavelength(s) of light that is desired to be used, such as silicon. However, an advantage of the embodiments described herein is that the support substrate 301 may not be transparent to the wavelengths of light and may be any suitable support material, whether transparent, translucent, or opaque to the light. In addition, the support substrate 301 may be attached using, e.g., an adhesive (not separately illustrated). However, in other embodiments, the support substrate 301 may be bonded to the first semiconductor device 200 and the gap-fill material 213 using, e.g., a bonding process. Any suitable method of attaching the support substrate 301 may be used.

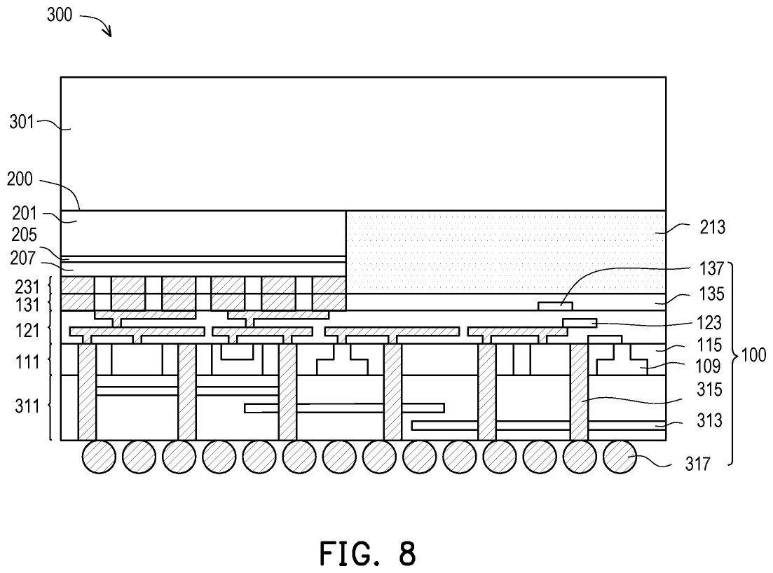

FIG. 8 illustrates a removal of the first substrate 101 and, optionally, the first insulating layer 103, thereby exposing the first active layer 111 of first optical components 109 of the optical interposer 100. In an embodiment, the first substrate 101 and the first insulating layer 103 may be removed using a planarization process, such as a chemical mechanical polishing process, a grinding process, one or more etching processes, combinations of these, or the like. However, any suitable method may be used in order to remove the first substrate 101 and/or the first insulating layer 103.

Once the first substrate 101 and the first insulating layer 103 have been removed, a second active layer 311 of fourth optical components 313 may optionally be formed on a back side of the first active layer 111. In an embodiment the second active layer 311 of fourth optical components 313 may be formed using similar materials and similar processes as the second optical components 123 of the first metallization layers 121 (see FIG. 5). For example, the second active layer 311 of fourth optical components 313 may be formed of alternating layers of a cladding material such as silicon oxide and core material such as silicon nitride formed using deposition and patterning processes in order to form optical components such as waveguides and the like.

FIG. 8 further illustrates formation of first through device vias (TDVs) 315 and formation of first external connectors 317 to form the optical package 300. In an embodiment, the first through device vias 315 extend through the second active layer 311 and the first active layer 111 so as to provide a quick passage of power, data, and ground through the optical interposer 100. In an embodiment, the first through device vias 315 may be formed by initially forming through device via openings into the optical interposer 100. The through device via openings may be formed by applying and developing a suitable photoresist (not shown), and removing portions of the second active layer 311 and the optical interposer 100 that are exposed.

Once the through device via openings have been formed within the optical interposer 100, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may alternatively be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as a CMP, although any suitable removal process may be used.

Optionally, in some embodiments, once the first through device vias 315 have been formed, second metallization layers (not separately illustrated) may be formed in electrical connection with the first through device vias 315. In an embodiment, the second metallization layers may be formed similarly as described above with respect to the first metallization layers 121, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

The first external connectors 317 may be formed to provide conductive regions for contact between either the first through device vias 315 or the second metallization layers to other external devices. The first external connectors 317 may be conductive bumps (e.g., C4 bumps, ball grid arrays, microbumps, etc.) or conductive pillars utilizing materials such as solder and copper. In an embodiment, in which the first external connectors 317 are contact bumps, the first external connectors 317 may comprise a material such as tin, or other suitable materials, such as silver, lead-free tin, or copper. In an embodiment, in which the first external connectors 317 are tin solder bumps, the first external connectors 317 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

As discussed in greater detail below, after forming the external connectors 317, the optical package 300 may be incorporated into a semiconductor package. For example, an optical port is incorporated into the semiconductor package to provide a mechanism for optical signals to be input to or output from the optical package 300 (e.g., the optical interposer 100). For example, the optical port serves as an optical input/output port to the optical interposer 100. In accordance with various embodiments discussed below, the optical port may have a variety of configurations and be incorporated into the semiconductor package in a variety of layouts.

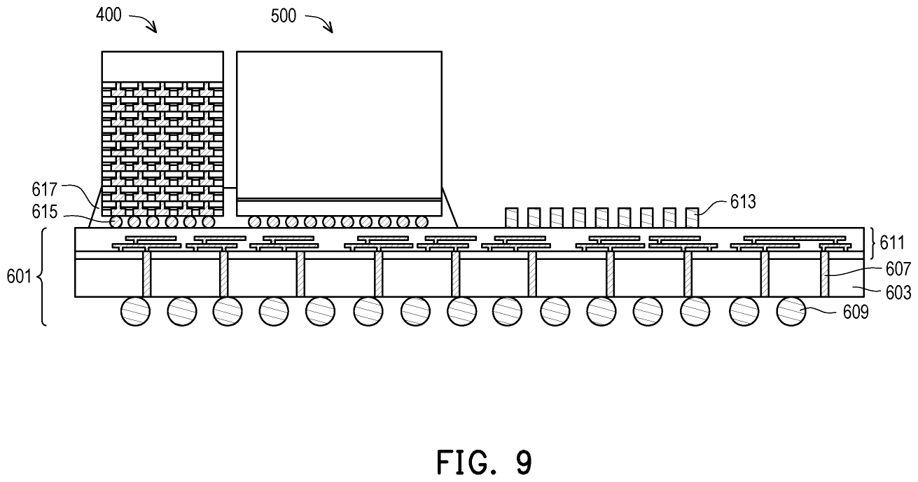

FIG. 9 illustrates a bonding of a second semiconductor device 400 and a third semiconductor device 500 to an interposer substrate 601. The interposer substrate 601 will be used to couple the optical package 300 (which will be subsequently attached), the second semiconductor device 400, and the third semiconductor device 500 with other devices to form, for example, a chip-on-wafer-on-substrate (CoWoS®). In an embodiment, the interposer substrate 601 comprises a semiconductor substrate 603, third metallization layers 611, second through device vias (TDVs) 607, and second external connectors 609. The semiconductor substrate 603 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Optionally, first active devices (not separately illustrated) may be added to the semiconductor substrate 603. The first active devices comprise a wide variety of active devices and passive devices such as capacitors, resistors, inductors and the like that may be used to generate the desired structural and functional requirements of the design for the semiconductor substrate 603. The first active devices may be formed using any suitable methods either within or else on the semiconductor substrate 603.

The third metallization layers 611 are formed over the semiconductor substrate 603 and the first active devices and are designed to connect the various active devices to form functional circuitry. In an embodiment, the third metallization layers 611 are formed of alternating layers of dielectric (e.g., low-k dielectric materials, extremely low-k dielectric material, ultra low-k dielectric materials, combinations of these, or the like) and conductive material and may be formed through any suitable process (such as deposition, damascene, dual damascene, etc.). However, any suitable materials and processes may be utilized.

Additionally, at any desired point in the manufacturing process, the second TDVs 607 may be formed within the semiconductor substrate 603 and, if desired, one or more layers of the third metallization layers 611, in order to provide electrical connectivity from a front side of the semiconductor substrate 603 to a back side of the semiconductor substrate 603. In an embodiment, the second TDVs 607 may be formed by initially forming through device via (TDV) openings into the semiconductor substrate 603 and, if desired, any of the overlying third metallization layers 611 (e.g., after the desired third metallization layer 611 has been formed but prior to formation of the next overlying third metallization layer 611). The TDV openings may be formed by applying and developing a suitable photoresist, and removing portions of the underlying materials that are exposed to a desired depth. The TDV openings may be formed so as to extend into the semiconductor substrate 603 to a depth greater than the eventual desired height of the semiconductor substrate 603.

Once the TDV openings have been formed within the semiconductor substrate 603 and/or any third metallization layers 611, the TDV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used.

Once the liner has been formed along the sidewalls and bottom of the TDV openings, a barrier layer may be formed and the remainder of the TDV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TDV openings. Once the TDV openings have been filled, excess liner, barrier layer, seed layer, and first conductive material outside of the TDV openings may be removed through a planarization process such as a CMP, although any suitable removal process may be used.

Once the TDV openings have been filled, the semiconductor substrate 603 may be thinned until the second TDVs 607 have been exposed. In an embodiment, the semiconductor substrate 603 may be thinned using, e.g., a chemical mechanical polishing process, a grinding process, or the like. Further, once exposed, the second TDVs 607 may be recessed using, e.g., one or more etching processes, such as a wet etch process in order to recess the semiconductor substrate 603 so that the second TDVs 607 extend out of the semiconductor substrate 603.

In an embodiment, the second external connectors 609 may be placed on the semiconductor substrate 603 in electrical connection with the second TDVs 607 and may be, e.g., a ball grid array (BGA) which comprises a eutectic material such as solder, although any suitable materials may be used. Optionally, an underbump metallization or additional metallization layers (not separately illustrated) may be utilized between the semiconductor substrate 603 and the second external connectors 609. In an embodiment in which the second external connectors 609 are solder bumps, the second external connectors 609 may be formed using a ball drop method, such as a direct ball drop process. In another embodiment, the solder bumps may be formed by initially forming a layer of tin through any suitable method such as evaporation, electroplating, printing, solder transfer, and then performing a reflow in order to shape the material into the desired bump shape. Once the second external connectors 609 have been formed, a test may be performed to ensure that the structure is suitable for further processing.

Optionally, the interposer substrate 601 further includes conductive pillars 613 formed over the third metallization layers 611. The conductive pillars 613 may be used to connect the optical package 300 to the interposer substrate 601. In some embodiments, the conductive pillars 613 are tall pillars in order for a height of the conductive pillars 613 plus a height of the optical package 300 to be substantially the same or comparable with heights of the second semiconductor device 400 and the third semiconductor device 500.

In some embodiments, the second semiconductor device 400 is an electronic integrated circuit (EIC) device such as a stacked device that includes multiple, interconnected semiconductor substrates. For example, the second semiconductor device 400 may be a memory device such as a high bandwidth memory (HBM) module, a hybrid memory cube (HMC) module, or the like that includes multiple stacked memory dies. In such embodiments, the second semiconductor device 400 includes multiple semiconductor substrates interconnected by through device vias (TDVs). Each of the semiconductor substrates may (or may not) have a layer of active devices and an overlying interconnect structure, a bond layer, and associated bond pads in order to interconnect the multiple devices within the second semiconductor device 400.

Of course, while the second semiconductor device 400 is a HBM module in one embodiment, the embodiments are not restricted to the second semiconductor device 400 being an HBM module. Rather, the second semiconductor device 400 may be any suitable semiconductor device, such as a processor die or other type of functional die. In particular embodiments the second semiconductor device 400 may be an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

The third semiconductor device 500 may be another EIC device that is intended to work with both the optical package 300 and the second semiconductor device 400. In some embodiments, the third semiconductor device 500 may have a different functionality from the second semiconductor device 400, such as by being an ASIC device, or may have a same functionality as the second semiconductor device 400, such as by being another high bandwidth memory device.

In an embodiment, both the second semiconductor device 400 and the third semiconductor device 500 may be bonded to the interposer substrate 601 using, e.g., third external connections 615 along each of the semiconductor devices 400, 500. The third external connections 615 may be conductive bumps (e.g., ball grid arrays, microbumps, etc.) or conductive pillars utilizing materials such as solder and copper. In an embodiment in which the third external connections 615 are contact bumps, the third external connections 615 may comprise a material such as tin, or other suitable materials, such as silver, lead-free tin, or copper. In an embodiment in which the third external connections 615 are tin solder bumps, the third external connections 615 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Additionally, once the third external connections 615 have been placed, the second semiconductor device 400 and the third semiconductor device 500 are aligned with the interposer substrate 601. Once aligned and in physical contact, the third external connections 615 are reflowed by raising the temperature of the third external connections 615 past a eutectic point of the third external connections 615, thereby shifting the material of the third external connections 615 to a liquid phase. Once reflowed, the temperature is reduced in order to shift the material of the third external connections 615 back to a solid phase, thereby bonding the second semiconductor device 400 and the third semiconductor device 500 to the interposer substrate 601.

Once the second semiconductor device 400 and the third semiconductor device 500 have been bonded, an underfill material 617 may be placed. The underfill material 617 may reduce stress and protect the joints resulting from the reflowing of the third external connections 615. The underfill material 617 may be formed by a capillary flow process after the second semiconductor device 400 and the third semiconductor device 500 are attached.

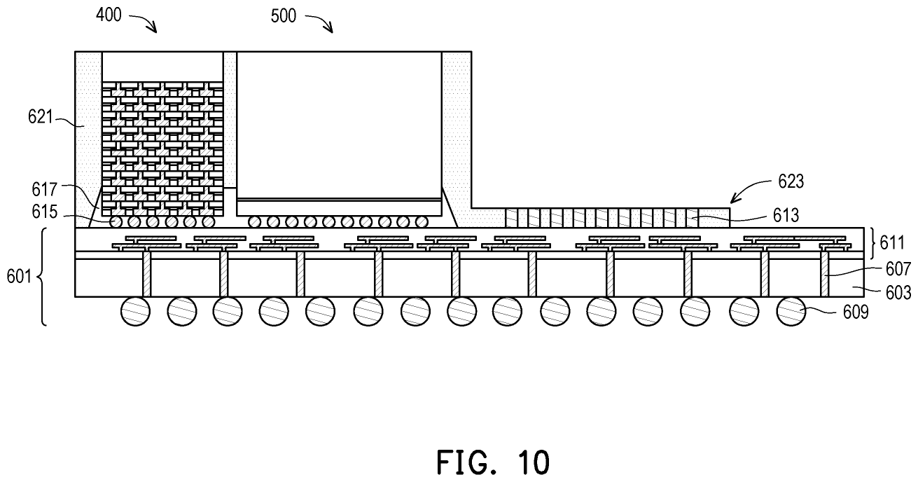

FIG. 10 illustrates that, after the underfill material 617 has been placed, the second semiconductor device 400, the third semiconductor device 500, and the conductive pillars 613 (if present) may be encapsulated with an encapsulant 621. In an embodiment, the encapsulant 621 may be a molding compound, epoxy, or the like. The encapsulant 621 may be applied by compression molding, transfer molding, or the like. The encapsulant 621 is further placed in gap regions between the second semiconductor device 400, the third semiconductor device 500, and the conductive pillars 613. The encapsulant 621 may be applied in liquid or semi-liquid form and then subsequently cured.

A planarization process is performed on the encapsulant 621 once the encapsulant 621 has been placed. Once planarized, top surfaces of the encapsulant 621, the second semiconductor device 400, and the third semiconductor device 500 are substantially coplanar within process variations. The planarization process may be, for example, a CMP, a grinding process, or the like. In some embodiments, the planarization may be omitted.

Following the planarization process, a removal process may be performed to remove a portion of the encapsulant 621 above the conductive pillars 613, thereby exposing the conductive pillars 613. The removal process may include one or more processes including laser cutting, plasma cutting, or any suitable method. The etched encapsulant 621 and the conductive pillars 613 form a platform 623 for attaching the optical package 300. In some embodiments, the encapsulant 621 is partially or fully removed from a region of the interposer substrate 601 adjacent to the platform 623.

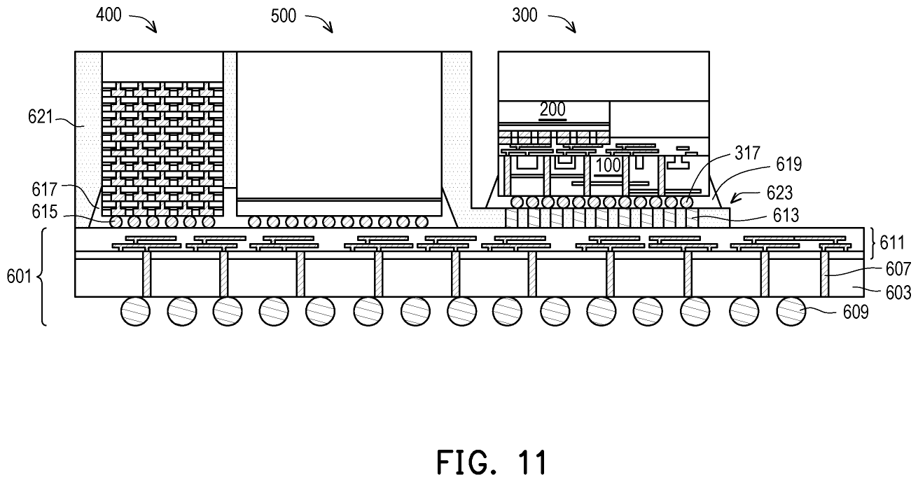

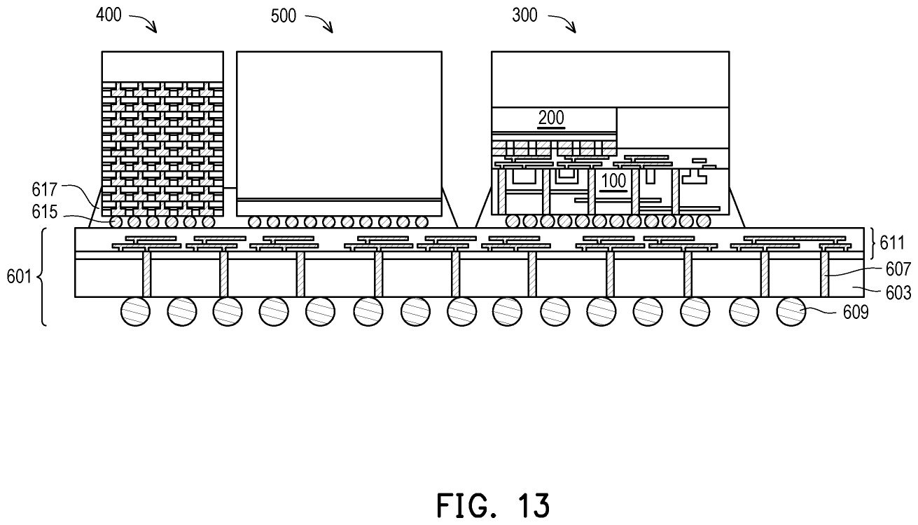

FIG. 11 illustrates that the optical package 300 may be attached to the interposer substrate 601, which is used to couple the optical package 300 with the other devices of the semiconductor package. For example, the optical package 300 may be attached to the platform 623 on the interposer substrate 601. In an embodiment, the optical package 300 may be attached to the platform 623 by aligning the first external connectors 317 with the conductive pillars 613 along the interposer substrate 601. Once aligned and in physical contact, the first external connectors 317 are reflowed by raising the temperature of the first external connectors 317 past a eutectic point of the first external connectors 317, thereby shifting the material of the first external connectors 317 to a liquid phase. Once reflowed, the temperature is reduced in order to shift the material of the first external connectors 317 back to a solid phase, thereby bonding the optical package 300 to the interposer substrate 601. In some embodiments (see FIGS. 13-17), the interposer substrate 601 does not include the conductive pillars 613, and the optical package 300 is attached to conductive features along the exposed surface of the third metallization layers 611, similarly as described above in connection with the second and third semiconductor devices 400, 500.

Once the optical package 300 has been bonded, an underfill material 619 may be placed. The underfill material 619 may reduce stress and protect the joints resulting from the reflowing of the first external connections 317. The underfill material 619 may be formed similarly as described above in connection with the underfill material 617 such as by a capillary flow process after the optical package 300 is attached.

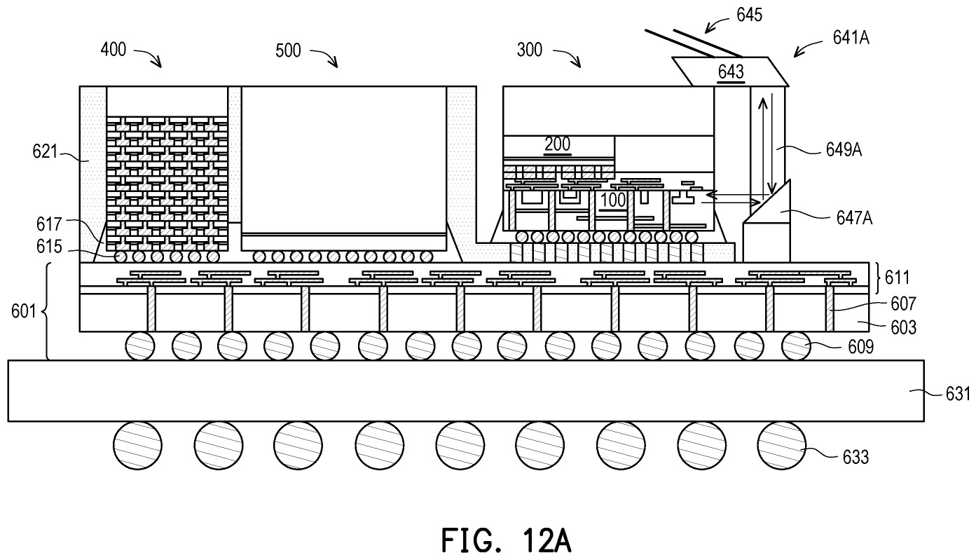

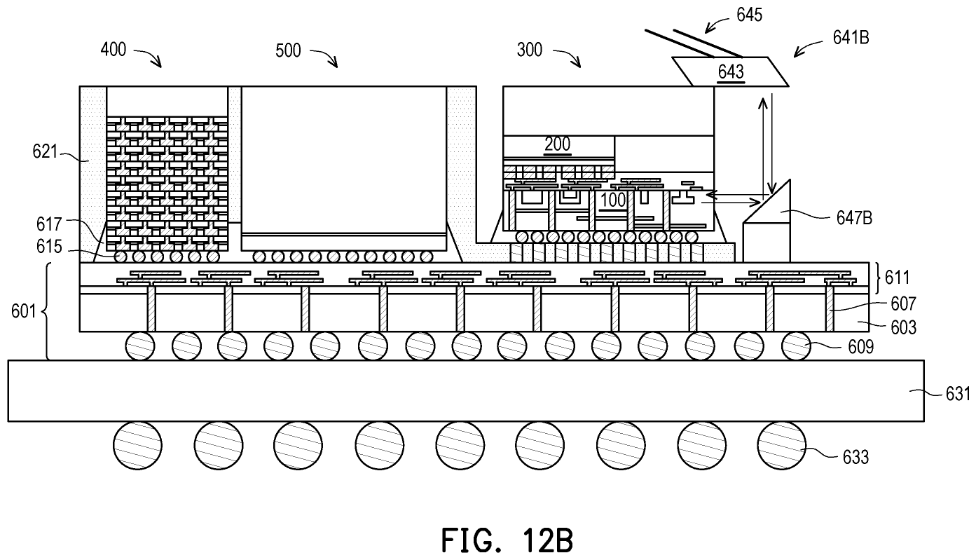

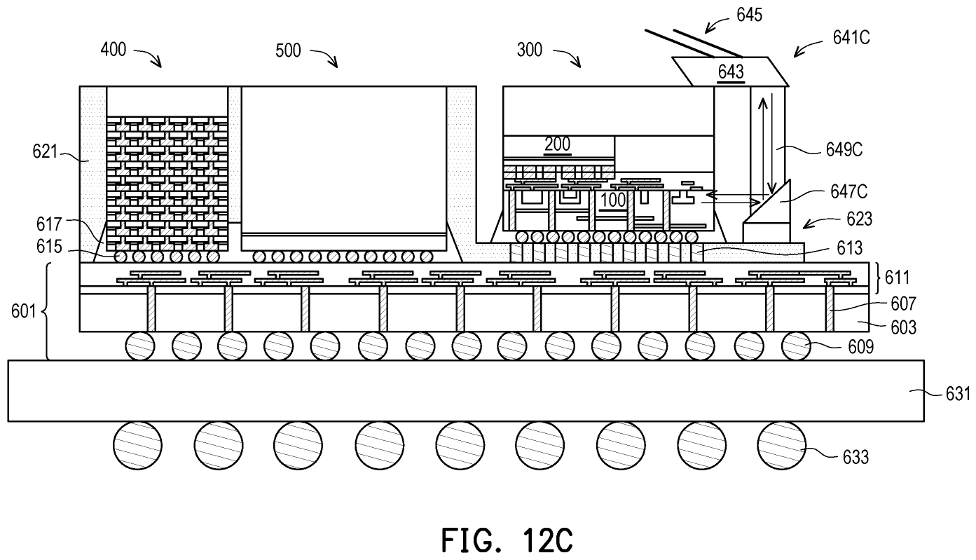

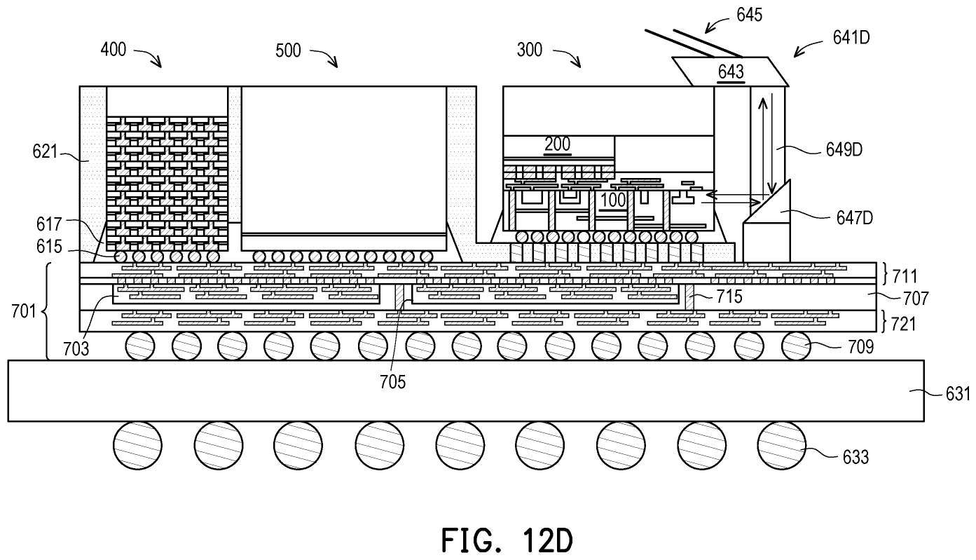

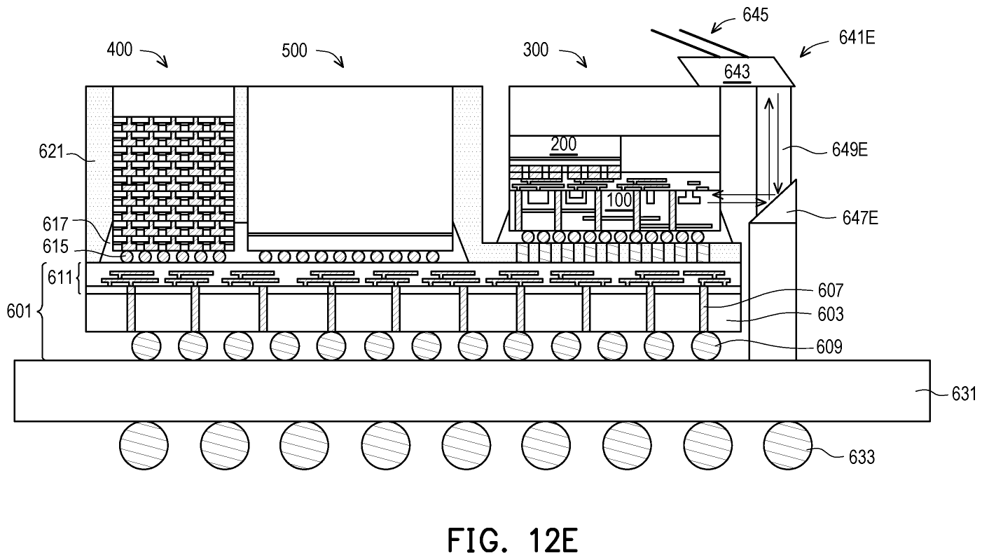

FIGS. 12A-12E illustrate various embodiments of an optical port 641 being attached and integrated with the optical package 300, the second semiconductor device 400, the third semiconductor device 500, and the interposer substrate 601 to form the semiconductor package. The optical port 641 is utilized as an optical input/output port to the optical interposer 100. As discussed in greater detail below, various embodiments of the optical port 641 may correspond with various embodiment semiconductor packages. Other features of these semiconductor packages may be substantially the same as one another, unless otherwise specified or illustrated.

After attaching the optical package 300 and the optical port 641 to the interposer substrate 601, the interposer substrate 601 may be bonded to a second substrate 631 with, e.g., the second external connectors 609. In an embodiment, the second substrate 631 may be a package substrate, which may be a printed circuit board (PCB) or the like. The second substrate 631 may include one or more dielectric layers and electrically conductive features, such as conductive lines and vias. In some embodiments, the second substrate 631 may include through-vias, active devices, passive devices, and the like. The second substrate 631 may further include conductive pads (not specifically illustrated) formed at the upper and lower surfaces of the second substrate 631.

The second external connectors 609 may be aligned with corresponding conductive connections on the second substrate 631. Once aligned, the second external connectors 609 may then be reflowed in order to bond the second substrate 631 to the interposer substrate 601. However, any suitable bonding process may be used to connect the interposer substrate 601 to the second substrate 631.

Additionally, the second substrate 631 may be prepared for further processing by forming fourth external connections 633 on an opposite side of the second substrate 631 from the optical package 300. In an embodiment, the fourth external connections 633 may be formed using similar processes and materials as the second external connectors 609. However, any suitable materials and processes may be utilized.

Still referring to FIGS. 12A-12E, the optical port 641 includes a fiber array unit 643 and a redirection structure 647 (e.g., a light redirection structure). The fiber array unit 643 is a feature that organizes and directs optical fibers 645 in a particular direction for the semiconductor package to receive or transmit optical signals. The redirection structure 647 redirects the optical signal, e.g., from the optical fibers 645 into the optical interposer 100. Optionally, the optical port 641 further includes a transparent medium 649 through which the optical signal passes. For example, the transparent medium 649 the optical signal to pass from the optical fibers 645 to the redirection structure 647 to the optical interposer 100—or in reverse. In an embodiment, the fiber array unit 643 is placed so as to optically couple the optical fibers 645 with certain optical components of the optical interposer 100. In accordance with various embodiments, these optical components include the first optical components 109, the second optical components 123, or the third optical components 137. In particular, these optical components may be edge couplers 109E of the first active layer 111 discussed above in connection with FIG. 2. Similarly, the fiber array unit 643 is positioned so that optical signals leaving the first optical components 109 (e.g., an edge coupler 109E) of the first active layer 111 are directed to the redirection structure 647 and redirected into the optic fibers 645 for transmission. However, any suitable location may be utilized.

In the illustrated embodiments, the fiber array unit 643 may be secured above the transparent medium 647 and/or over the optical package 300. As shown, the optical signal follows a substantially vertical path from the fiber array unit 643, and the optical signal follows a substantially horizontal path to the edge couplers 109E. The redirection structure 647 redirects the optical signal to align the substantially vertical path with the substantially horizontal path. An advantage of the redirection structure 647 is that the fiber array unit 643 may be secured in various accessible locations of the completed semiconductor package. In some embodiments, the fiber array unit 643 may be secured to the semiconductor package using a suitable adhesive such as an optical glue (not specifically illustrated). In some embodiments, the optical glue comprises a polymer material such as epoxy-acrylate oligomers, and may have a refractive index between about 1 and about 3. However, any suitable material may be utilized. Moreover, while the fiber array unit 643 is illustrated as being attached to the semiconductor package at this point in the manufacturing process, in some embodiments, the fiber array unit 643 may be attached during any suitable subsequent step in the process.

During operation of the semiconductor package, the optical components (e.g., the edge couplers 109E) of the optical interposer 100 are powered by light from both the optical fibers 645. After reaching the optical interposer 100, waveguides within the first optical components 109, the second optical components 123, or the third optical components 137 route the received optical signals as desired, and converters within the first optical components 109, the second optical components 123, or the third optical components 137 may convert the received optical signals into electrical signals before sending those electrical signals to other devices, such as the first semiconductor device 200. By the same token, the optical fibers 645 can also serve as an output for optical signals generated by the first optical components 109, the second optical components 123, or the third optical components 137, such that the optical port 641 serves as an I/O port for the optical signals.

In accordance with various embodiments, the optical fibers 645 are attached to the fiber array unit 643 to serve as entry or exit points for the optical signals. In an embodiment (not separately illustrated), the fiber array unit 643 comprises a fiber array substrate and lids to align the optic fibers 645. For example, the fiber array substrate comprises a substrate material into which a plurality of grooves are formed for alignment of the individual optical fibers 645. The optical fibers 645 may be placed into the individual grooves, and the lids are placed around the optical fibers 645 in order to constrain and control the optical fibers 645. However, any suitable structure for the fiber array unit 643 may be utilized.

Referring to FIG. 12A, the semiconductor package may utilize an optical port 641A that includes a redirection structure 647A and a transparent medium 649A to redirect optical signals between, e.g., optical components of the optical interposer 100 and the optical fibers 645. For example, the redirection structure 647A may be a prism mounted on the interposer substrate 601 and secured with an adhesive or by any suitable means. In addition, the transparent medium 649A may be a glass such as a silicate or a plastic material disposed above the redirection structure 647A and secured with an adhesive (e.g., an optical glue, which is not specifically illustrated) or by any suitable means. In some embodiments (not specifically illustrated), the transparent medium 649A may further include a piece disposed between the optical interposer 100 and the redirection structure 647A.

The fiber array unit 643 may be secured to top surfaces of the optical package 300 and/or the transparent medium 649A with an adhesive (e.g., an optical glue, which is not specifically illustrated) or by any suitable means. As illustrated, the optical signal from the optical fibers 645 (e.g., attached within the fiber array unit 643) passes through the transparent medium 649A and is redirected by the redirection structure 647A to optical components (e.g., the edge couplers 109E) of the optical interposer 100.

Referring to FIG. 12B, the semiconductor package may utilize an optical port 641B that includes a redirection structure 647B to redirect optical signals between, e.g., optical components of the optical interposer 100 and the optical fibers 645. For example, the redirection structure 647B may be a prism (e.g., similarly as the redirection structure 647A) mounted on the interposer substrate 601 and secured with an adhesive or by any suitable means. As illustrated, the optical port 641B may exclude a transparent medium such that the optical signal passes through air or a vacuum rather than a glass or a plastic material.

The fiber array unit 643 may be secured to the top surface of the optical package 300 similarly as described above, and the optical fiber 643 may hover above the redirection structure 647B. In some embodiments (not separately illustrated), the fiber array unit 643 is secured directly over the optical package 300 such that the optical signal from the optical fibers 645 reaches the redirection structure 647B at an angle from the vertical. As such, the redirection structure 647B is chosen with a desired shape and positioned in such a way as to redirect the angled optical signal to a substantially horizontal path to the optical components (e.g., the edge couplers 109E) of the optical interposer 100.

Referring to FIG. 12C, the semiconductor package may utilize an optical port 641C that includes a redirection structure 647C and a transparent medium 649C to redirect optical signals between, e.g., optical components of the optical interposer 100 and the optical fibers 645. For example, the redirection structure 647C may be a prism mounted on a portion of the platform 623 laterally adjacent to the optical package 300 (e.g., on the encapsulant 621 laterally displaced from the conductive pillars 613). The redirection structure 647C may be secured to the platform 623 with an adhesive or by any suitable means. In addition, the transparent medium 649C may be a similar material and similarly secured as described above in connection with the transparent medium 649A. In some embodiments (not specifically illustrated), the transparent medium 649C may further include a piece disposed between the optical interposer 100 and the redirection structure 647C.

The fiber array unit 643 may be secured to top surfaces of the optical package 300 and/or the transparent medium 649C similarly as described above. As illustrated, the optical signal from the optical fibers 645 passes through the transparent medium 649C and is redirected by the redirection structure 647C to optical components (e.g., the edge couplers 109E) of the optical interposer 100. In some embodiments (not specifically illustrated), the transparent medium 649C may be omitted, similarly as described above in connection with the optical port 641B. In such embodiments, the redirection structure 647C may be chosen with a desired shape and positioned in such a way as to redirect angled light from the optical fibers 645 (e.g., secured directly over the optical package 300) to a substantially horizontal path to the edge couplers 109E of the optical interposer 100.

Referring to FIG. 12D, the semiconductor package may utilize an optical port 641D that includes a redirection structure 647D and a transparent medium 649D to redirect optical signals between, e.g., optical components of the optical interposer 100 and the optical fibers 645. For example, the redirection structure 647D may be a prism mounted on a redistribution interposer 701 (e.g., instead of the interposer substrate 601). The redirection structure 647D may be secured to the redistribution interposer 701 with an adhesive or by any suitable means. In addition, the transparent medium 649D may be a similar material and similarly secured as described above in connection with the other transparent mediums 649.

The fiber array unit 643 may be secured to top surfaces of the optical package 300 and/or the transparent medium 649D similarly as described above. As illustrated, optical signal from the optical fibers 645 passes through the transparent medium 649D to optical components (e.g., the edge couplers 109E) of the optical interposer 100. In some embodiments (not specifically illustrated), the transparent medium 649D may be omitted, similarly as described above in connection with the optical port 641B. In such embodiments, the redirection structure 647D may be chosen with a desired shape and positioned in such a way as to redirect angled light from the optical fibers 645 (e.g., secured directly over the optical package 300) to a substantially horizontal path to the edge couplers 109E of the optical interposer 100.

As noted above, the embodiment illustrated in FIG. 12D provides an embodiment of the semiconductor package in which the optical package 300, the second semiconductor device 400, and the third semiconductor device 500 are bonded to the redistribution interposer 701, which may be, e.g., an integrated fan-out (InFO) substrate. In this embodiment, before those bonding steps, InFO TDVs 715 may be initially formed (using, e.g., a photolithographic masking and plating process) on a substrate (not separately illustrated) adjacent to a fourth semiconductor device 703 and a fifth semiconductor device 705, which may be similar as described above in connection with the second semiconductor device 400 and/or the third semiconductor device 500. Once in place, the InFO TDVs 715, the fourth semiconductor device 703, and the fifth semiconductor device 705 are encapsulated with a second encapsulant 707 (similar to the encapsulant 621), and fourth metallization layers 711 (similar to the first metallization layers 121) may be formed. The substrate may then be removed, and fifth metallization layers 721 may be formed on an opposite side of the InFO TDVs 715.

Once the redistribution interposer 701 has been formed, the second semiconductor device 400 and the third semiconductor device 500 may be bonded to it using the third external connections 615, and the optical package 300 may be attached using the first external connectors 317. Additionally, the interposer substrate 701 may be bonded to the second substrate 631 using, e.g., fifth external connectors 709, and the fourth external connections 633 are formed on the second substrate 631. However, any suitable processes and structures may be utilized.

Referring to FIG. 12E, the semiconductor package may have an optical port 641E that includes a redirection structure 647E and a transparent medium 649E to redirect light between, e.g., optical components of the optical interposer 100 and the optical fibers 645. As illustrated, the redirection structure 647E may be a prism mounted on the second substrate 631 (e.g., instead of on the interposer substrate 601 or the redistribution interposer 701). The redirection structure 647E may be secured to the second substrate 631 with an adhesive or by any suitable means. In addition, the transparent medium 649E may be a similar material and similarly secured as described above in connection with the other transparent mediums 649. The fiber array unit 643 may be secured to top surfaces of the optical package 300 and/or the medium component 649E similarly as described above. As illustrated, the optical signal from the optical fibers 645 passes through the transparent medium 649E to the edge couplers 109E of the optical interposer 100. In some embodiments (not specifically illustrated), the transparent medium 649E may be omitted, similarly as described above in connection with the optical port 641B. In such embodiments, the redirection structure 647E may be chosen with a desired shape and positioned in such a way as to redirect angled light from the optical fibers 645 (e.g., secured directly over the optical package 300) to a substantially horizontal path to the edge couplers 109E of the optical interposer 100.

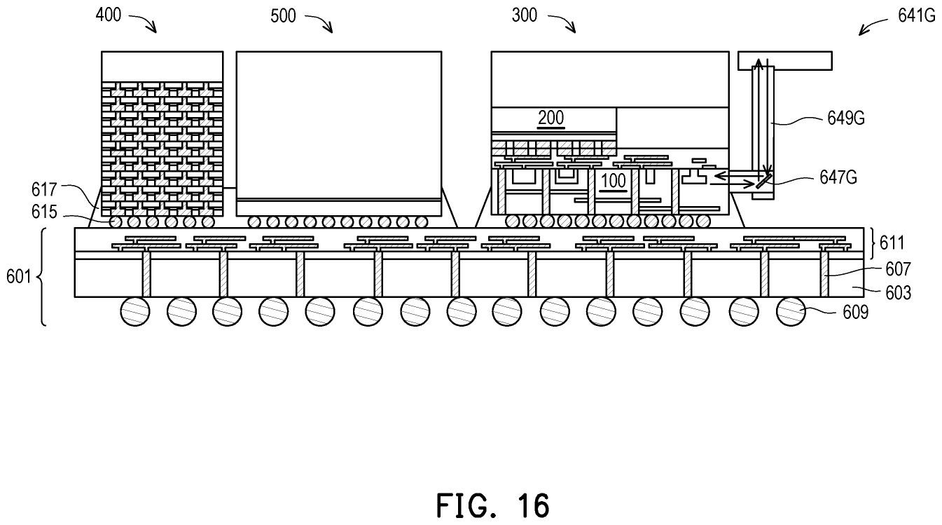

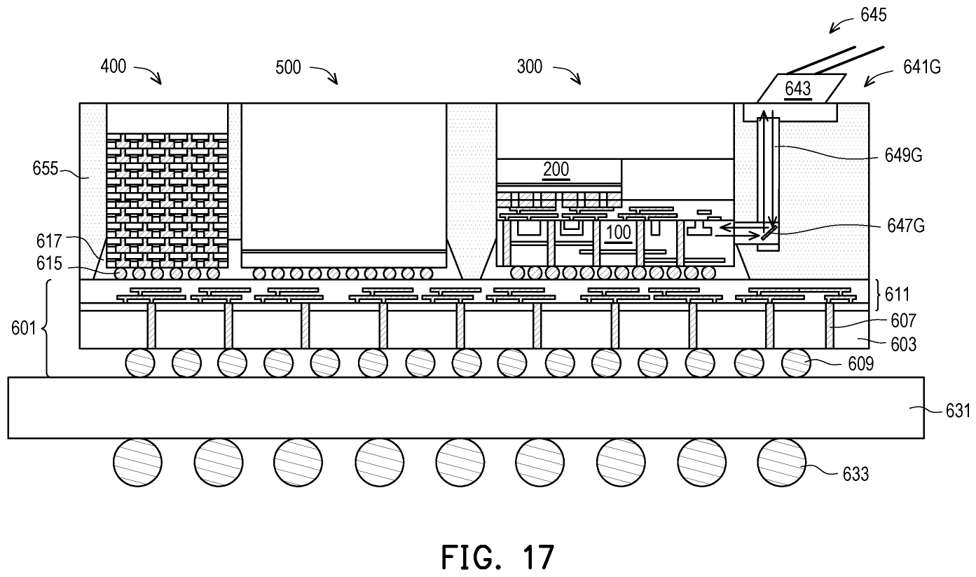

FIGS. 13-17 illustrate various additional embodiments of the semiconductor package. For example, FIGS. 13-15 depict mount-last embodiments for attaching an optical port 641F, wherein the optical port 641F is attached after the optical package 300 is attached to the interposer substrate 601. In addition, FIGS. 16-17 depict mount-first embodiments for attaching an optical port 641G, wherein the optical port 641G is attached to the optical package 300 before the optical package 300 is attached to the interposer substrate 601. The features illustrated and described in the following embodiments may be formed and attached similarly as the analogous features described above, unless otherwise stated.

FIGS. 13-15 illustrate the mount-last embodiments of forming a semiconductor package, in accordance with various embodiments. FIG. 13 illustrates the optical package 300, the second semiconductor device 400, and the third semiconductor device 500 being attached to the interposer substrate 601, similarly as described above. As shown, the optical package 300 may be attached directly to the third metallization layers 611 without conductive pillars (e.g., the conductive pillars 613) being formed along the interposer substrate 601. However, in some embodiments (not specifically illustrated), the optical package 300 may be attached to conductive pillars, similarly as described above in connection with FIGS. 9-11. In such embodiments, the second semiconductor device 400 and the third semiconductor device are attached first, and the encapsulant 621 may be formed and etched before attaching the first optical interposer 300.

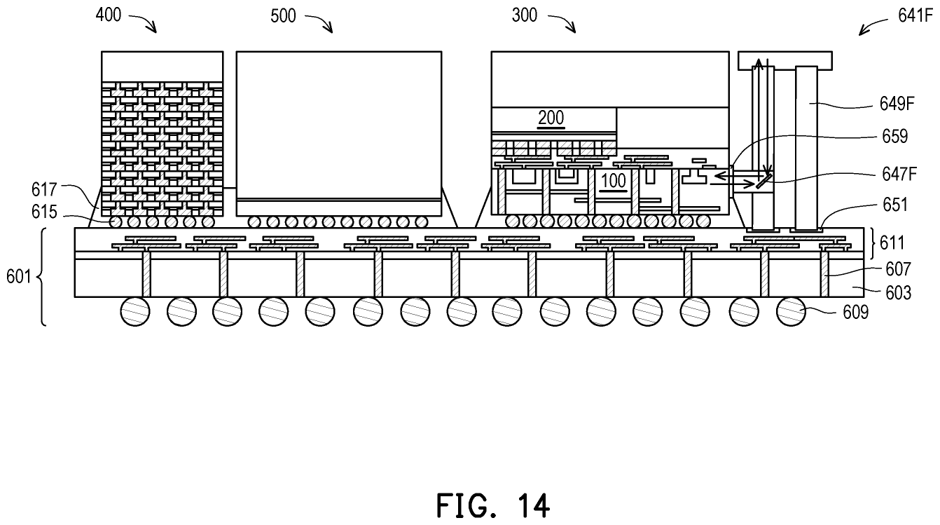

FIG. 14 illustrates that, after attaching the optical package 300 the semiconductor package, an optical port 641F is attached to the semiconductor package. In some embodiments, one or more recesses may be etched into a top surface of the interposer substrate 601, and an adhesive 651 such as a glue or epoxy may be deposited in the recesses. As discussed below, the optical port 641F may then be attached to the adhesive 651 in a location laterally adjacent to the optical package 300.

In accordance with some embodiments, the optical port 641F includes a redirection structure 647F that is housed within a transparent medium 649F before attachment to the interposer substrate 601. For example, the redirection structure 647F may be a reflector which is angled to redirect an optical signal between the subsequently attached optical fibers 645 and optical components (e.g., edge couplers 109E) of the optical interposer 100. In addition, the transparent medium 649F may be a glass or plastic material that is transparent to the optical signal. As such, the redirection structure 647F may be encapsulated during formation or shaping of the transparent medium 649F. However, the redirection structure 647F and the transparent medium 649F may be formed by any suitable means. The optical port 641F further includes a fiber array unit 643 to secure the optical fibers 645. The optical port 641F is secured in place against the interposer substrate 601 by the adhesive 651, and the transparent medium 649F may be further secured in place against the optical package 300 with another adhesive or optical glue (not specifically illustrated).

In some embodiments, the transparent medium 649F may include a plurality of “legs” for improved stability against the interposer substrate 601. In other embodiments, the transparent medium 649F may have a wide base (e.g., a single leg) for improved stability against the interposer substrate 601. In addition, the transparent medium 649F may include an “arm” for stability against the optical package 300. Further, the transparent medium 649F may include a “cap” upon which the fiber array unit 643 is attached (see FIG. 16). Although not specifically illustrated, the cap of the transparent medium 649F may extend similarly as the arm against the optical package 300 for improved stability, and the cap may be secured with any suitable adhesive or glue, whether transparent or opaque.

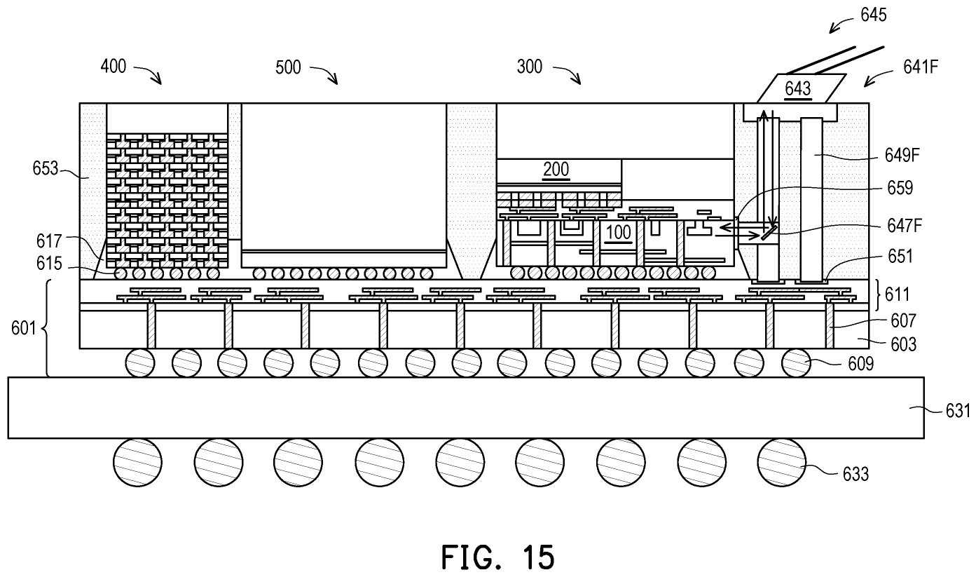

FIG. 15 illustrates that, after the optical port 641F has been placed, the optical package 300, the second semiconductor device 400, the third semiconductor device 500, and the optical port 641F are encapsulated with an encapsulant 653, similarly as described above in connection with the encapsulant 621. In an embodiment, the encapsulant 653 may be a molding compound, epoxy, or the like. The encapsulant 653 may be applied by compression molding, transfer molding, or the like. The encapsulant 653 is further placed in gap regions between the optical package 300, the second semiconductor device 400, the third semiconductor device 500, and the optical port 641F. The encapsulant 653 may be applied in liquid or semi-liquid form and then subsequently cured.

A planarization process is performed on the encapsulant 653 once the encapsulant 653 has been placed. Once planarized, top surfaces of the encapsulant 653, the optical package 300, the second semiconductor device 400, and the third semiconductor device 500 are substantially coplanar within process variations. The planarization process may be, for example, a CMP, a grinding process, or the like. In some embodiments, the planarization may be omitted.

FIG. 15 further illustrates that, after forming the encapsulant 653, the optical fiber 643 may be attached over the medium component 649F. In some embodiments, a cleaning or removal process (e.g., a chemical cleaning) may be performed to expose a top surface of the transparent medium 649F through the encapsulant 653 (if remaining above). The fiber array unit 643 may be placed so as to optically couple the optical fibers 645 and optical components (e.g., the edge couplers 109E) of the optical interposer 100. For example, the fiber array unit 643 may be secured to the semiconductor package using a suitable adhesive such as, e.g., an optical glue (not specifically illustrated). In some embodiments, the optical glue comprises a polymer material such as epoxy-acrylate oligomers, and may have a refractive index between about 1 and about 3. However, any suitable material may be utilized.

In addition, the interposer substrate 601 may be bonded to a second substrate 631 with, e.g., the second external connectors 609. In an embodiment, the second substrate 631 may be a package substrate, which may be a PCB or the like. The second substrate 631 may include one or more dielectric layers and electrically conductive features, such as conductive lines and vias. In some embodiments, the second substrate 631 may include through-vias, active devices, passive devices, and the like. The second substrate 631 may further include conductive pads formed at the upper and lower surfaces of the second substrate 631.

The second external connectors 609 may be aligned with corresponding conductive connections on the second substrate 631. Once aligned the second external connectors 609 may then be reflowed in order to bond the second substrate 631 to the interposer substrate 601. However, any suitable bonding process may be used to connect the interposer substrate 601 to the second substrate 631.

Additionally, the second substrate 631 may be prepared for further processing by forming fourth external connections 633 on an opposite side of the second substrate 631 from the optical package 300. In an embodiment, the fourth external connections 633 may be formed using similar processes and materials as the second external connectors 609. However, any suitable materials and processes may be utilized. It should be appreciated that features described in connection with FIGS. 12A-12E may be substituted for features illustrated or described in connection with FIGS. 13-15, where applicable.

FIGS. 16-17 illustrate the mount-first embodiments of forming a semiconductor package, in accordance with various embodiments. FIG. 16 illustrates the second semiconductor device 400 and the third semiconductor device 500 being attached to the interposer substrate 601, similarly as described above. In addition, an optical port 641G is attached to the optical package 300 before attaching the optical package 300 (and the optical port 641G) to the semiconductor package. Similarly as previous embodiments (see FIGS. 13-15), the optical package 300 may be attached directly to the third metallization layers 611 without conductive pillars (e.g., the conductive pillars 613) being formed along the interposer substrate 601. However, in some embodiments (not specifically illustrated), the optical package 300 may be attached to conductive pillars, similarly as described above in connection with FIGS. 9-11. In such embodiments, the second semiconductor device 400 and the third semiconductor device are attached first, and the encapsulant 621 may be formed and etched before attaching the first optical interposer 300.

In accordance with some embodiments, the optical port 641G includes a redirection structure 647G that is housed within a transparent medium 649G before attachment to the interposer substrate 601, similarly as described above in connection with the redirection structure 647F. For example, the redirection structure 647G may be a reflector which is angled to redirect an optical signal between the subsequently attached optical fibers 645 and optical components (e.g., edge couplers 109E) of the optical interposer 100. In addition, the transparent medium 649G may be a glass or plastic material that is transparent to the optical signal. As such, the redirection structure 647G may be encapsulated during formation or shaping of the transparent medium 649G. However, the redirection structure 647G and the transparent medium 649G may be formed by any suitable means. The transparent medium 649G may be secured in place against the optical package 300 with an adhesive or optical glue (not specifically illustrated).

In some embodiments, the transparent medium 649G may include a plurality of “legs” for improved stability against the optical package 300 (e.g., as opposed to being secured against the interposer substrate 601). In some embodiments (not specifically illustrated), the transparent medium 649G may include an “arm” for stability against the interposer substrate 601. However, in the illustrated embodiment, the transparent medium 649G is displaced from the interposer substrate 601. Further, the transparent medium 649F includes a “cap” upon which the fiber array unit 643 is attached (see FIG. 17). Although not specifically illustrated, the legs of the transparent medium 649F may be secured with a suitable adhesive, wherein at least the leg adjacent to the optical components of the optical interposer 100 is secured with a transparent adhesive such as an optical glue 659.

FIG. 17 illustrates that, after the optical package 300 and the optical port 641G have been placed, the optical package 300, the second semiconductor device 400, the third semiconductor device 500, and the optical port 641G are encapsulated with an encapsulant 655, similarly as described above in connection with the encapsulants 621, 655. In an embodiment, the encapsulant 655 may be a molding compound, epoxy, or the like. The encapsulant 655 may be applied by compression molding, transfer molding, or the like. The encapsulant 655 is further placed in gap regions between the optical package 300, the second semiconductor device 400, the third semiconductor device 500, and the optical port 641G. The encapsulant 655 may be applied in liquid or semi-liquid form and then subsequently cured.

A planarization process is performed on the encapsulant 655 once the encapsulant 655 has been placed. Once planarized, top surfaces of the encapsulant 655, the optical package 300, the second semiconductor device 400, and the third semiconductor device 500 are substantially coplanar within process variations. The planarization process may be, for example, a CMP, a grinding process, or the like. In some embodiments, the planarization may be omitted.

FIG. 17 further illustrates that, after forming the encapsulant 655, the fiber array unit 643 may be attached over the transparent medium 649G. In some embodiments, a cleaning or removal process (e.g., a chemical cleaning) may be performed to expose a top surface of the transparent medium 649G through the encapsulant 653 (if remaining above). The fiber array unit 643 may be placed so as to optically couple the optical fibers 645 and optical components (e.g., the edge couplers 109E) of the optical interposer 100. For example, the fiber array unit 643 may be secured to the semiconductor package using a suitable adhesive such as, e.g., an optical glue (not specifically illustrated). In some embodiments, the optical glue comprises a polymer material such as epoxy-acrylate oligomers, and may have a refractive index between about 1 and about 3. However, any suitable material may be utilized.

In addition, the interposer substrate 601 may be bonded to a second substrate 631 with, e.g., the second external connectors 609. In an embodiment, the second substrate 631 may be a package substrate, which may be a PCB or the like. The second substrate 631 may include one or more dielectric layers and electrically conductive features, such as conductive lines and vias. In some embodiments, the second substrate 631 may include through-vias, active devices, passive devices, and the like. The second substrate 631 may further include conductive pads formed at the upper and lower surfaces of the second substrate 631.

The second external connectors 609 may be aligned with corresponding conductive connections on the second substrate 631. Once aligned the second external connectors 609 may then be reflowed in order to bond the second substrate 631 to the interposer substrate 601. However, any suitable bonding process may be used to connect the interposer substrate 601 to the second substrate 631.

Additionally, the second substrate 631 may be prepared for further processing by forming fourth external connections 633 on an opposite side of the second substrate 631 from the optical package 300. In an embodiment, the fourth external connections 633 may be formed using similar processes and materials as the second external connectors 609. However, any suitable materials and processes may be utilized. It should be appreciated that features described in connection with FIGS. 12A-12E may be substituted for features illustrated or described in connection with FIGS. 16-17, where applicable.

Various advantages are achieved. In particular, embodiments of the optical port 641 allow for optical inputs to be received (or optical outputs to be transmitted) by edge couplers 109E in the optical interposer 100 of the optical package 300 of a semiconductor package. Edge couplers 109E tend to have a greater bandwidth for optical signals than other optical components such as grating couplers. In addition, the edge couplers 109E may receive or transmit the optical signal through less material by following a substantially horizontal pathway through a side of the optical interposer 100 as opposed to passing through more material through a top or bottom of the optical interposer, thereby reducing signal loss or distortion. For example, the optical port 641 redirects the substantially horizontal pathway of the optical signal to have a substantially vertical pathway in relation to optical fibers 645 above the optical package 300 and the optical port 641. Similarly, the optical port 641 redirects optical signals from the optical fibers 645 to be aligned with the edge couplers 109E of the optical interposer 100.

In an embodiment, a method includes: forming an optical package, forming the optical package comprising: forming optical devices over a substrate; forming a first interconnect structure over the optical devices; and attaching a first semiconductor device to the optical devices; attaching a second semiconductor device to an interposer substrate; attaching the optical package to the interposer substrate; and attaching an optical port adjacent to the optical package, the optical port comprising: an optical fiber; and an optical redirection structure configured to redirect an optical signal between a first pathway and a second pathway, the first pathway being parallel with a major surface of the interposer substrate, the second pathway being non-parallel with the major surface of the interposer substrate. In another embodiment, the optical redirection structure comprises a prism. In another embodiment, the optical port further comprises a glass medium between the optical fiber and the optical redirection structure. In another embodiment, the optical devices comprise an edge coupler, the edge coupler being configured to receive or transmit the optical signal along the first pathway. In another embodiment, the optical fiber comprises a fiber array unit, the fiber array unit being configured to receive or transmit the optical signal along the second pathway. In another embodiment, the method further includes: forming an encapsulant over the second semiconductor device and conductive pillars of the interposer substrate; and cutting the encapsulant to form a platform and to expose the conductive pillar. In another embodiment, attaching the optical package to the interposer substrate comprises attaching the optical package to the platform. In another embodiment, attaching the optical port adjacent to the optical package comprises attaching the optical port to the platform. In another embodiment, the method further includes attaching an interposer substrate to a package substrate, wherein attaching the optical port adjacent to the optical package comprises attaching the optical port to the package substrate.

In an embodiment, a semiconductor device includes: an interposer substrate; an optical package over the interposer substrate, the optical package comprising: an optical interposer comprising optical devices; a first semiconductor device over the optical interposer; and a substrate over the first semiconductor device; and an optical port over the interposer substrate, the optical port comprising: a glass medium being adhered to the optical interposer; a redirection structure embedded in the glass medium; and an optical fiber attached to the glass medium. In another embodiment, the optical package and the optical port are embedded in an encapsulant. In another embodiment, the optical port is adhered to the interposer substrate by a first adhesive layer. In another embodiment, the optical port is adhered to the substrate of the optical package by a second adhesive layer, and wherein the optical port is adhered to the optical interposer by an optical glue. In another embodiment, the optical port is displaced from the interposer substrate. In another embodiment, the redirection structure comprises a reflector.

In an embodiment, a semiconductor device includes: an optical package over and electrically connected to an interposer substrate, the optical package comprising: an optical interposer comprising an edge coupler; a first semiconductor device over and electrically connected to the optical interposer; and a support substrate over the first semiconductor device; an optical port adjacent to the optical package, the optical port configured to direct an optical signal to and from the edge coupler, the optical port comprising an optical redirection structure; a second semiconductor device over and electrically connected to the interposer substrate; and an encapsulant encapsulating lateral edges of the second semiconductor device, a portion of the encapsulant being directly below the optical package. In another embodiment, the optical port further comprises a fiber array unit disposed above the optical redirection structure. In another embodiment, the optical redirection structure comprises a prism. In another embodiment, the prism is mounted on the encapsulant. In another embodiment, the optical redirection structure comprises a reflector, and wherein the reflector is embedded in a transparent medium.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an optical package, forming the optical package comprising:
forming optical devices over a substrate;
forming a first interconnect structure over the optical devices; and
attaching a first semiconductor device to the optical devices;
attaching a second semiconductor device to an interposer substrate;
attaching the optical package to the interposer substrate; and
attaching an optical port adjacent to the optical package, the optical port comprising:
an optical fiber; and
an optical redirection structure configured to redirect an optical signal between a first pathway and a second pathway, the first pathway being parallel with a major surface of the interposer substrate, the second pathway being non-parallel with the major surface of the interposer substrate.

2. The method of claim 1, wherein the optical redirection structure comprises a prism.

3. The method of claim 1, wherein the optical port further comprises a glass medium between the optical fiber and the optical redirection structure.

4. The method of claim 1, wherein the optical devices comprise an edge coupler, the edge coupler being configured to receive or transmit the optical signal along the first pathway.

5. The method of claim 1, wherein the optical fiber comprises a fiber array unit, the fiber array unit being configured to receive or transmit the optical signal along the second pathway.

6. The method of claim 1, further comprising:
forming an encapsulant over the second semiconductor device and conductive pillars of the interposer substrate; and
cutting the encapsulant to form a platform and to expose the conductive pillar.

7. The method of claim 6, wherein attaching the optical package to the interposer substrate comprises attaching the optical package to the platform.

8. The method of claim 6, wherein attaching the optical port adjacent to the optical package comprises attaching the optical port to the platform.

9. The method of claim 8, further comprising attaching an interposer substrate to a package substrate, wherein attaching the optical port adjacent to the optical package comprises attaching the optical port to the package substrate.

10. A semiconductor package, comprising:
an interposer substrate;
an optical package over the interposer substrate, the optical package comprising:
an optical interposer comprising optical devices;
a first semiconductor device over the optical interposer; and
a substrate over the first semiconductor device; and
an optical port over the interposer substrate, the optical port comprising:
a glass medium being adhered to the optical interposer;
a redirection structure embedded in the glass medium; and
an optical fiber attached to the glass medium.

11. The semiconductor package of claim 10, wherein the optical package and the optical port are embedded in an encapsulant.

12. The semiconductor package of claim 10, wherein the optical port is adhered to the interposer substrate by a first adhesive layer.

13. The semiconductor package of claim 10, wherein the optical port is adhered to the substrate of the optical package by a second adhesive layer, and wherein the optical port is adhered to the optical interposer by an optical glue.

14. The semiconductor package of claim 13, wherein the optical port is displaced from the interposer substrate.

15. The semiconductor package of claim 10, wherein the redirection structure comprises a reflector.

16. A semiconductor package, comprising:
an optical package over and electrically connected to an interposer substrate, the optical package comprising:
an optical interposer comprising an edge coupler;
a first semiconductor device over and electrically connected to the optical interposer; and
a support substrate over the first semiconductor device;
an optical port adjacent to the optical package, the optical port configured to direct an optical signal to and from the edge coupler, the optical port comprising an optical redirection structure;
a second semiconductor device over and electrically connected to the interposer substrate; and
an encapsulant encapsulating lateral edges of the second semiconductor device, a portion of the encapsulant being directly below the optical package.

17. The semiconductor package of claim 16, wherein the optical port further comprises a fiber array unit disposed above the optical redirection structure.

18. The semiconductor package of claim 16, wherein the optical redirection structure comprises a prism.

19. The semiconductor package of claim 18, wherein the prism is mounted on the encapsulant.

20. The semiconductor package of claim 16, wherein the optical redirection structure comprises a reflector, and wherein the reflector is embedded in a transparent medium.
